(19) United States
(12) Patent Application Publication
(10) Pub. No.: US 2021/0033928 A1
(43) Pub. Date: Feb. 4, 2021

(54) LIGHT SOURCE SUBSTRATE, BACKLIGHT DEVICE, AND DISPLAY DEVICE

(71) Applicant: SHARP KABUSHIKI KAISHA, Sakai City (JP)

(72) Inventors: KAITO YAMURA, Sakai City (JP); SHIGENORI TANAKA, Sakai City (JP)

(21) Appl. No.: 16/943,605

(22) Filed: Jul. 30, 2020

Related U.S. Application Data
(60) Provisional application No. 62/882,161, filed on Aug. 2, 2019.

(51) Int. Cl. G02F 1/13357; H01L 27/15

(52) U.S. Cl. CPC G02F 1/133603; H01L 27/156

(57) ABSTRACT

A light source substrate includes a substrate portion; a plurality of light sources mounted on the substrate portion in a row; a first terminal portion that is included in any of the plurality of light sources; a second terminal portion that is included in a light source, which is adjacent to the light source including the first terminal portion, of the plurality of light sources and that is fitted to the first terminal portion to be coupled to the first terminal portion; and a common pad that is disposed at a position at which the common pad overlaps the first terminal portion and the second terminal portion which fit each other on the substrate portion and that is connected to the first terminal portion and the second terminal portion which fit each other.

### CROSS-REFERENCE TO RELATED APPLICATION

The present application claims priority from Provisional Application No. 62/882,161, the content to which is hereby incorporated by reference into this application.

### BACKGROUND OF THE INVENTION

### 1. Field of the Invention

The present invention relates to a light source substrate, a backlight device, and a display device.

### 2. Description of the Related Art

In recent years, there has been a strong demand to increase the display area of a liquid crystal display device while maintaining the external size of the liquid crystal display device. In addition, to improve design, there has been a strong demand for picture-frame narrowing in which a picture-frame portion of a liquid crystal display device is reduced. One problem with picture-frame narrowing is generation of hot spots (luminance unevenness in which luminance is locally high in part of an area of a screen) which is the result of short distances, to the display area, from chip LEDs, which are mounted at an interval on a picture-frame portion. In a case where the distance from the chip LEDs to the display area is constant, when the chip LEDs are mounted at a narrower interval, it is possible to suppress generation of hot spots. Accordingly, to prevent generation of the hot spot while achieving picture-frame narrowing, it is necessary to mount the chip LEDs on the picture-frame portion at a narrow pitch, and, as a technique therefor, techniques described in Japanese Unexamined Patent Application Publication No. 2015-165525 and International Publication No. 2009/028612 below are known.

According to Japanese Unexamined Patent Application Publication No. 2015-165525, electronic components are connected by a wire that passes outside of an area between pads to which adjacent electronic components are respectively connected, and a good solder fillet is thereby formed on each terminal, such that it is possible to provide a flexible printed circuit board on which the electronic components are able to be mounted at a narrower pitch while sufficient bonding strength is secured. Further, International Publication No. 2009/028612 describes that a light emitting device in which an interval between adjacent chip LEDs is decreased and which is able to prevent short circuit is able to be provided by providing mounting bases, on which the chip LEDs are respectively mounted, on an insulating base material.

### SUMMARY OF THE INVENTION

According to Japanese Unexamined Patent Application Publication No. 2015-165525 described above, the flexible printed circuit board on which chip LEDs to be connected to each other are mounted adjacently is provided with a land to which a terminal of one chip LED on a side of the other chip LED is connected and a land to which a terminal of the other chip LED on a side of the one chip LED is connected. The two lands are connected by a wire passing outside of an area that has an approximately strip shape formed by connecting end portions of the two lands in a width direction or end portions of the two lands in a thickness direction with a straight line. In this manner, even in a case where an interval between the two lands is narrow, when a terminal is soldered, it is possible to suppress flow of molten solder from one land to the other land along the wire, thus making it possible to secure sufficient bonding strength in each of the lands. It is described that an interval between two chip LEDs is thus able to be further narrowed, while maintaining sufficient bonding strength.

Further, it is described that, according to the light emitting device described in International Publication No. 2009/028612 above, by forming the mounting bases on a wiring substrate and mounting the chip LEDs thereon, generation of voids in a bonding section between a chip LED and a metal layer is suppressed and pitch reduction is enabled while short circuit between the chip LEDs is prevented. However, neither Japanese Unexamined Patent Application Publication No. 2015-165525 nor International Publication No. 2009/028612 refers to a technique by which, among chip LEDs that are mounted on a substrate and adjacent to each other, a terminal portion of one chip LED and a terminal portion of the other chip LED, which is adjacent to the one chip LED, on a side of the one chip LED are mounted on the same pad on the substrate while also achieving pitch reduction.

An aspect of the invention has been completed on the basis of such circumstances and aims to enable light sources to be mounted on a light source substrate at a narrow pitch and achieve picture-frame narrowing while suppressing luminance unevenness (generation of a hot spot).

(1) An embodiment of the invention is a light source substrate including: a substrate portion; a plurality of light sources mounted on the substrate portion in a row; a first terminal portion that is included in any of the plurality of light sources; a second terminal portion that is included in a light source, which is adjacent to the light source including the first terminal portion, of the plurality of light sources and that is fitted to the first terminal portion to be coupled to the first terminal portion; and a common pad that is disposed at a position at which the common pad overlaps the first terminal portion and the second terminal portion which fit each other on the substrate portion and that is connected to the first terminal portion and the second terminal portion which fit each other.

(2) Further, an embodiment of the invention is the light source substrate, in which the first terminal portion includes a protrusion that protrudes in a row direction of the light sources and the second terminal portion includes a recess that accepts the protrusion, in addition to a configuration of (1) described above.

(3) Further, an embodiment of the invention is the light source substrate, in which the protrusion has a shape that protrudes in the row direction of the light sources in plan view and the recess has a recessed shape that accepts the protrusion in plan view, in addition to a configuration of (2) described above.

(4) Further, an embodiment of the invention is the light source substrate, in which the protrusion has a shape including a portion a width of which is wider at a location further from the light source than at a location closer to the light source in plan view and the recess has a recessed shape that accepts the protrusion in plan view, in addition to the configuration of (2) described above.

(5) Further, an embodiment of the invention is the light source substrate, in which the first terminal portion includes a first protruding portion that projects to a side of the second terminal portion and a first angled portion that is bent from a tip end of a projection of the first protruding portion and the second terminal portion includes a second protruding portion that projects to a side of the first terminal portion and a second angled portion that is bent from a tip end of a projection of the second protruding portion, in addition to the configuration of (1) described above.

(6) Further, an embodiment of the invention is the light source substrate, in which each of the plurality of light sources includes the first terminal portion at one end portion in a row direction and includes the second terminal portion at the other end portion, in addition to a configuration of any one of (1) described above to (5) described above.

(7) Further, an embodiment of the invention is a backlight device including: the light source substrate according to any one of (1) described above to (6) described above; and a light guide plate that includes a light entering end surface on which light emitted from the light sources is incident and a light emitting plate surface from which the light is emitted.

(8) Further, an embodiment of the invention is a display device including: the backlight device according to (7) described above; and a display panel that displays an image by utilizing the light emitted from the backlight device.

According to an aspect of the present invention, it is possible to achieve picture-frame narrowing while suppressing occurrence of luminance unevenness.

### BRIEF DESCRIPTION OF DRAWINGS

FIG. 1 is an exploded perspective view of a liquid crystal display device according to Embodiment 1 of the invention.

FIG. 2 is a sectional view taken along line A-A of FIG. 1.

FIG. 3 is a plan view illustrating a state of chip LEDs mounted on a substrate portion (Embodiment 1).

FIG. 4 is a perspective view illustrating shapes of a first terminal portion and a second terminal portion (Embodiment 1).

FIG. 5 is a plan view illustrating an operation when the first terminal portion and the second terminal portion are fitted (Embodiment 1).

FIG. 6 is a plan view illustrating a state where the first terminal portion and the second terminal portion are fitted (Embodiment 1).

FIG. 7 is a plan view illustrating a corresponding relationship between a pad disposed on a substrate portion and a terminal portion of a chip LED (related art).

FIG. 8 is a plan view illustrating a corresponding relationship between a pad disposed on the substrate portion and a terminal portion of a chip LED (Embodiment 1).

FIG. 9 is a plan view illustrating a state where chip LEDs are coupled (Embodiment 1).

FIG. 10 is a plan view illustrating a state where chip LEDs are mounted on the substrate portion (related art).

FIG. 11 is a perspective view illustrating shapes of a first terminal portion and a second terminal portion (Embodiment 2).

FIG. 12 is a side view illustrating an operation when the first terminal portion and the second terminal portion are fitted (Embodiment 2).

FIG. 13 is a perspective view illustrating shapes of a first terminal portion and a second terminal portion (Embodiment 3).

FIG. 14 is a side view illustrating an operation when the first terminal portion and the second terminal portion are fitted (Embodiment 3).

FIG. 15 is a plan view illustrating a state where chip LEDs are mounted on a substrate portion (Embodiment 3).

FIG. 16 is a perspective view illustrating shapes of a first terminal portion and a second terminal portion (Embodiment 4).

FIG. 17 is a side view illustrating an operation when the first terminal portion and the second terminal portion are fitted (Embodiment 4).

FIG. 18 is a plan view illustrating a state where chip LEDs are mounted on a substrate portion (Embodiment 4).

### DETAILED DESCRIPTION OF THE INVENTION

### Embodiment 1

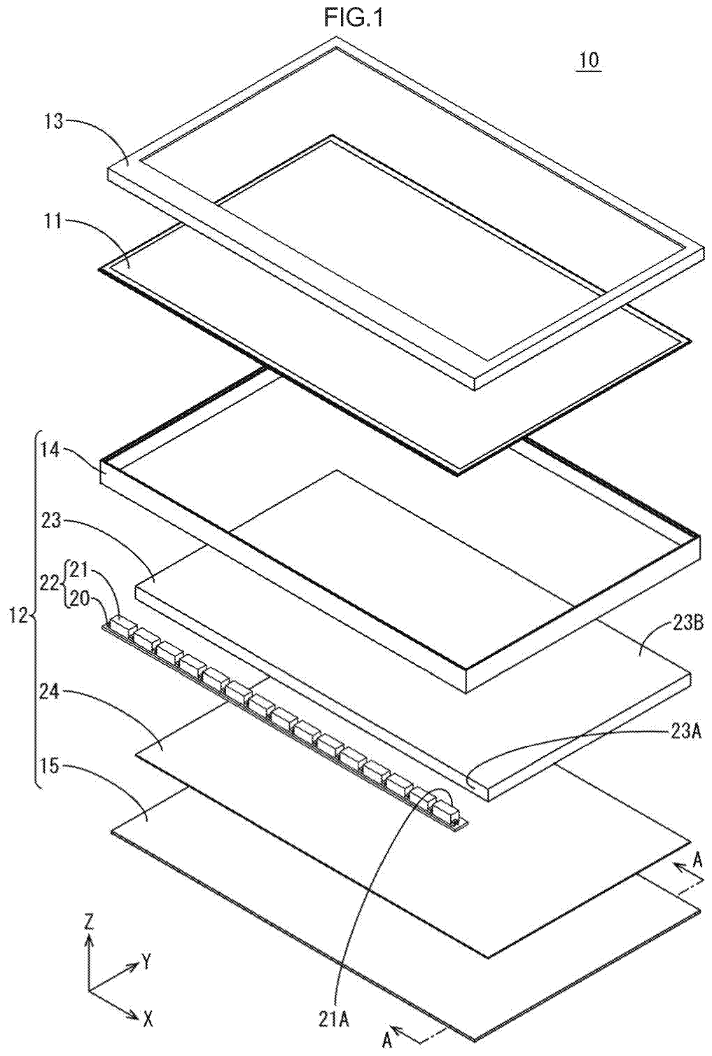

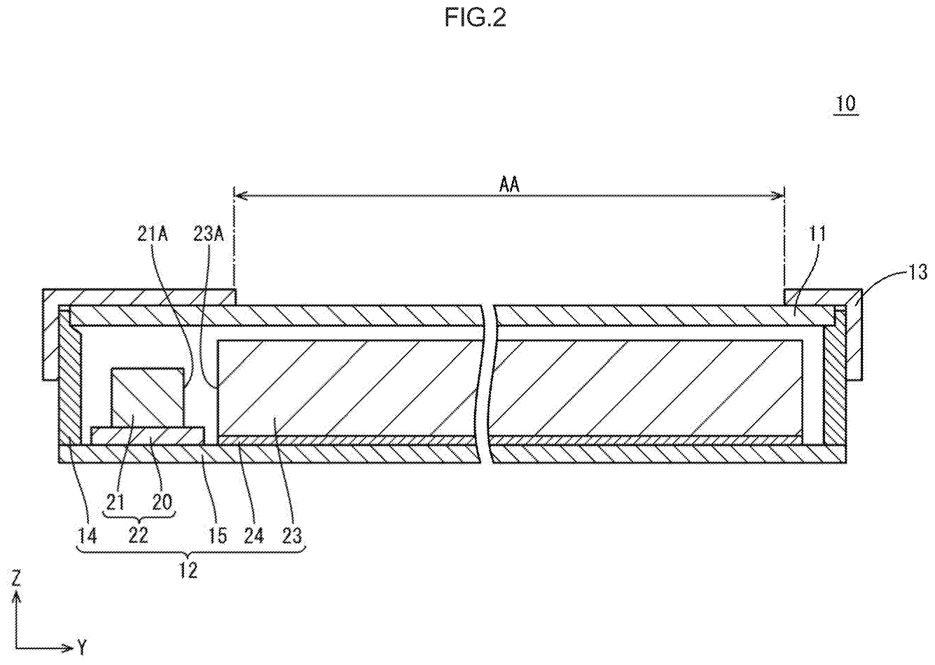

Embodiment 1 of the invention will be described with reference to FIGS. 1 to 10. In Embodiment 1, a backlight device 12 that includes an LED substrate (light source substrate) 22 and a liquid crystal display device (display device) 10 that uses the backlight device 12 are exemplified. Note that, an X-axis, a Y-axis, and a Z-axis are indicated at part of each drawing, and the direction of each axis is illustrated so as to correspond to the same direction in the respective figures. Further, FIG. 2 is a reference of an up-down direction, and an upper side of the figure is set as a front side and a lower side of the figure is set as a rear side.

As illustrated in an exploded perspective view of FIG. 1, the liquid crystal display device 10 includes a liquid crystal panel (display panel) 11 that displays an image and the backlight device 12 that illuminates the liquid crystal panel 11 with light, and the liquid crystal panel 11 and the backlight device 12 are integrally held by, for example, a bezel 13 that has a frame shape.

Next, the liquid crystal panel 11 and the backlight device 12 that constitute the liquid crystal display device 10 will be described in order. Of the liquid crystal panel 11 and the backlight device 12, the liquid crystal panel 11 has a quadrangular shape which is laterally elongated in plan view, and includes a pair of glass substrates bonded in a state of a predetermined gap provided therebetween, and a liquid crystal layer including molecules of a liquid crystal, which is a substance whose optical characteristics change in accordance with application of an electric field, is sealed between the two glass substrates. On an inner surface side of one glass substrate (array substrate, active matrix substrate), switching elements (for example, TFTs) which are connected to source wires and gate wires that are orthogonal to each other and pixel electrodes each of which is disposed in a quadrangular area surrounded by the source wires and the gate wires and which are connected to the switching elements are arranged in a planar matrix, and, in addition, an alignment film and the like are provided. On an inner surface side of the other glass substrate (counter substrate, CF substrate), a color filter in which coloring portions of R (red), G (green), B (blue), and the like are arranged in a planar matrix of a predetermined array is provided, and, in addition, a light shielding layer (black matrix) which is disposed between the coloring portions and has a lattice shape, a counter electrode in a solid state facing the pixel electrodes and, an alignment film, and the like are provided. Note that, in FIG. 2, on a front surface of the liquid crystal panel 11, an area overlapping an opening of the bezel 13 is an AA (active area) in which an image is able to be displayed. Further, a long-side direction of the liquid crystal panel 11 coincides with an X-axis direction, a short-side direction coincides with a Y-axis direction, and a thickness direction coincides with a Z-axis direction.

As illustrated in FIG. 1, the backlight device 12 includes at least the LED substrate (light source substrate) 22 that is constituted by a substrate portion 20 and chip LEDs (light sources) 21 mounted on the substrate portion 20, a light guide plate 23 that guides light from the chip LEDs 21 to the liquid crystal panel 11, and a reflective sheet 24 that is disposed on a rear side (side opposite to the liquid crystal panel 11) of the light guide plate 23. Further, the backlight device 12 includes a frame 14 in a frame shape that surrounds the light guide plate 23, the LED substrate 22, and the like, and a chassis 15 disposed on a rear side of the frame 14. In the backlight device 12 in the present embodiment, the LED substrate 22 is disposed on one end portion (on a near side in FIG. 1) of a pair of end portions on the long sides of the backlight device 12, and the respective chip LEDs 21 mounted on the substrate portion 20 of the LED substrate 22 are disposed unevenly close to one end portion on the long sides of the liquid crystal panel 11. That is, the backlight device 12 according to the present embodiment is an edge light type (side light type) of a single-side light entering type in which light from the chip LEDs 21 enters the light guide plate 23 from a single side only. Next, each component of the backlight device 12 will be described in detail.

The light guide plate 23 is plate-shaped and is formed of a synthetic resin material (for example, acrylic resin such as PMMA, polycarbonate, or the like), a refractive index of which is sufficiently higher than that of air, and which is almost transparent (excellent in transparency). As illustrated in FIGS. 1 and 2, the light guide plate 23 has a quadrangular shape, a size of which is almost the same as that of the liquid crystal panel 11 in plan view, and which is elongated laterally, and a long-side direction and a short-side direction of a plate surface thereof coincide with the X-axis direction and the Y-axis direction, respectively. The light guide plate 23 has functions of introducing light (light emitted in the Y-axis direction) from light emitting surfaces 21A of the chip LEDs 21 through a light entering end surface 23A, which is a side surface facing the light emitting surfaces 21A, changing the direction of light, which has entered the light entering end surface 23A, toward the liquid crystal panel 11 side while transmitting the light inside, and emitting the light from a light emitting plate surface 23B on a front side.

The reflective sheet 24 is disposed between the rear side of the light guide plate 23, that is, a plate surface on a side opposite to the light emitting plate surface 23B, and the chassis 15 so as to overlap the light guide plate 23 in plan view. A front surface of the reflective sheet 24 is white, a color having excellent light reflectivity, and, by reflecting light which has been transmitted in the light guide plate 23 and reached the surface on the rear side (side opposite to the light emitting plate surface 23B) of the light guide plate 23, the reflective sheet 24 changes the direction of light toward the front side, that is, the light emitting plate surface 23B.

The chassis 15 is made of metal, resin, or the like and has a quadrangular shape which overlaps the frame 14 in plan view and which is elongated laterally. The LED substrate 22 and the reflective sheet 24 are fixed to the chassis 15 with double-sided tape or the like.

The frame 14 is made of metal, resin, or the like and has a frame shape, which is elongated laterally, so as to surround the liquid crystal panel 11, the light guide plate 23, the LED substrate 22, and the like. The bezel 13 and the chassis 15 are fixed to the frame 14 with double-sided tape or the like.

Each of the chip LEDs 21 is a white LED that emits white light and is obtained by sealing a semiconductor element (blue LED chip) made from a compound semiconductor, such as, for example, InGaN within a package by using resin which contains a yellow phosphor, or the like. As illustrated in FIGS. 1 and 2, each chip LED 21 has an approximately parallelepiped shape, is arranged so that a bottom surface is in contact with the substrate portion 20, and is a side light emitting type in which one surface of side surfaces adjacent to the bottom surface is a light emitting surface 21A. Further, among the four side surfaces of the chip LED 21, two parallel surfaces adjacent to the light emitting surface 21A are provided with two terminal portions 31 in total (a first terminal portion 31A and a second terminal portion 31B) made of metal, which are electrically connected to the semiconductor element sealed inside, and the light emitting surface 21A emits white light when a predetermined voltage is applied between the two terminal portions 31.

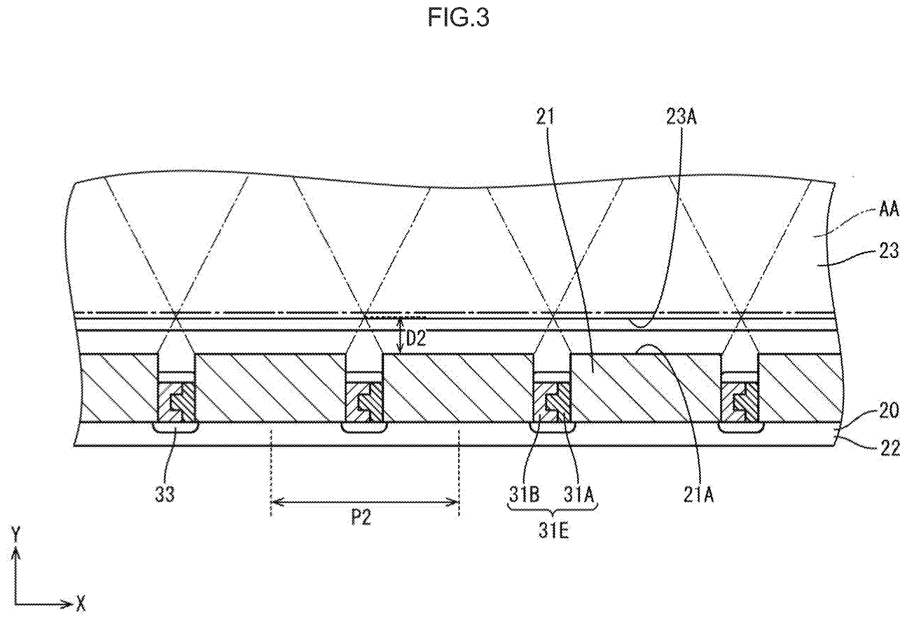

The substrate portion 20 is a flexible printed circuit board (FPC) in which a pad 32 formed of a metal film (for example, a copper film) and a wiring pattern are appropriately formed on a film made of an insulating material, such as polyimide, which has flexibility. As illustrated in FIG. 1, the substrate portion 20 has a narrow elongated shape that extends in a long-side direction (X-axis direction) of the chassis 15, and a front surface thereof is parallel to a plate surface of the chassis 15 and the plate surface of the light guide plate 23. That is, the substrate portion 20 has an orientation in which a long-side direction (length direction) and a short-side direction (width direction) of the front surface coincide with the X-axis direction and the Y-axis direction, respectively, and, furthermore, a thickness direction orthogonal to the front surface coincides with the Z-axis direction. Accordingly, as illustrated in FIG. 2, the light emitting surface 21A of the chip LED 21 of the side light emitting type mounted on the substrate portion 20 faces the light entering end surface 23A of the light guide plate 23. Further, an optical axis of each of the chip LEDs 21, that is, a propagation direction of light whose light emission intensity is highest coincides approximately with a direction normal to the light emitting surface 21A (direction normal to the light entering end surface 23A in the Y-axis direction), and although light emission intensity decreases as the angle from the normal direction increases, light is diffused within a range demarcated by the light emitting surface 21A and two one-dot chain lines extending from end portions of the light emitting surface 21A in FIG. 3.

Further, as illustrated in FIG. 3, common pads 33 made of metal and connected to the terminal portions 31A and 31B of the chip LEDs 21 are provided on the front surface of the substrate portion 20. Although details will be described later, the substrate portion 20 and the chip LEDs 21 are connected by applying solder paste onto a common pad 33, thereafter mounting the chip LEDs 21 on the front surface of the substrate portion 20 so that a coupled terminal portion 31E, which is formed of the terminal portions 31A and 31B, and the common pad 33 overlap, and thereafter performing a reflow process. Accordingly, the chip LEDs 21 are connected to the substrate portion 20 via solder, thereby forming the LED substrate 22.

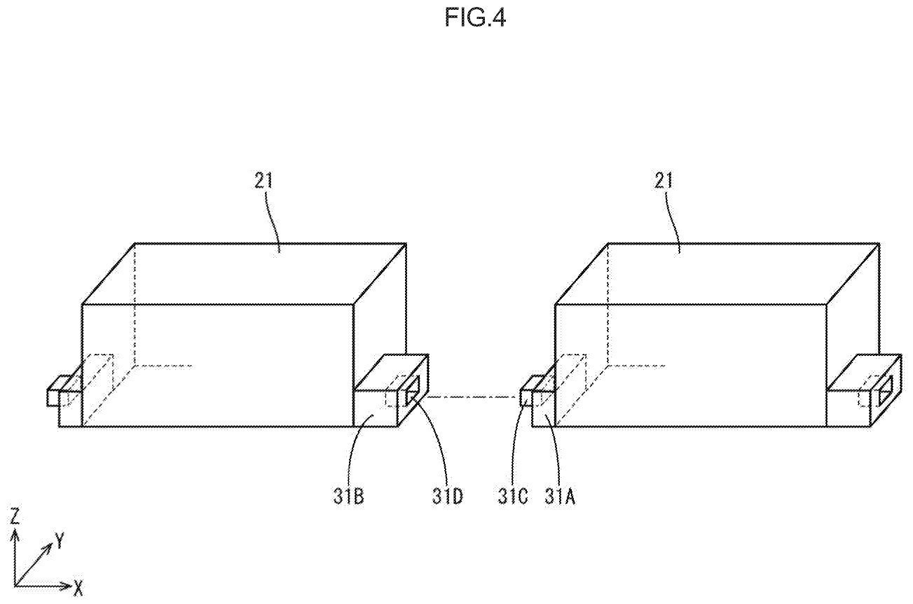

The two types of terminal portions 31A and 31B that are included in the chip LED 21 according to the present embodiment will be described in detail. When attention is paid to two chip LEDs 21 adjacent to each other mounted on the substrate portion 20, and when the terminal portion 31 that is included in one chip LED 21 on a side of the other chip LED 21 is the first terminal portion 31A and the terminal portion 31 that is included in the other chip LED 21 on a side of the one chip LED 21 is the second terminal portion 31B, the shapes of the two terminal portions 31A and 31B are provided so as to fit each other as illustrated in FIG. 4. Specifically, the first terminal portion 31A includes a protrusion 31C that protrudes in a row direction of the chip LEDs 21, and the second terminal portion 31B has a shape including a recess 31D that accepts the protrusion 31C.

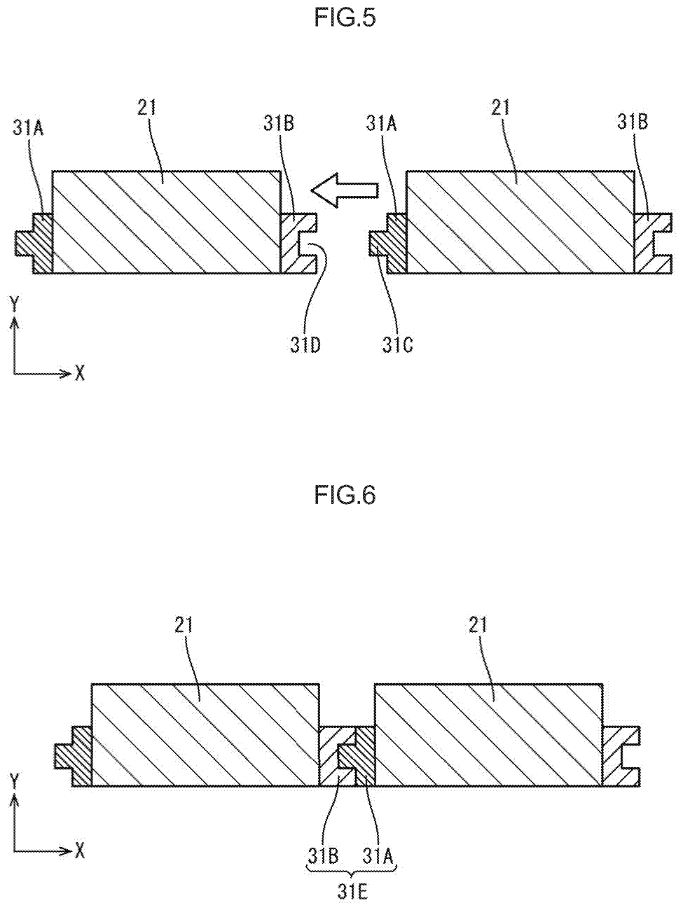

With such a configuration, as illustrated in FIGS. 5 and 6, when the two adjacent chip LEDs 21 are displaced in the row direction so as to be close to each other, the protrusion 31C of the first terminal portion 31A and the recess 31D of the second terminal portion 31B fit each other and are coupled, thereby forming the coupled terminal portion 31E. Accordingly, the two chip LEDs 21 are also coupled, such that relative displacement is regulated between the adjacent chip LEDs 21. Accordingly, occurrence of positional deviation between the adjacent chip LEDs 21 on the substrate portion 20 is suppressed.

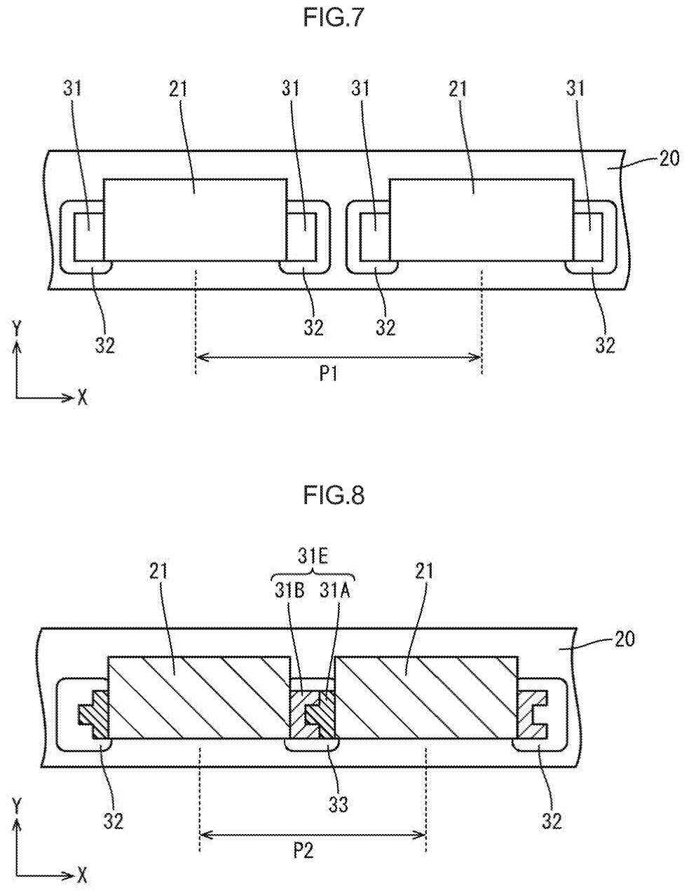

Next, the common pad 33 provided on the front surface of the substrate portion 20 according to the present embodiment will be described with reference to FIGS. 7 and 8. As illustrated in FIG. 7, in the related art, when two chip LEDs 21 are mounted on the substrate portion 20, pads 32 are provided so that each of the pads 32 corresponds to one terminal portion 31 on a one-to-one basis. In this manner, the chip LEDs 21 are mounted while occurrence of positional deviation is suppressed, but it is difficult to perform mounting at a pitch narrower than P1 illustrated in FIG. 7.

On the other hand, with the configuration according to the present embodiment, as illustrated in FIG. 8, the first terminal portion 31A and the second terminal portion 31B that are included in the two adjacent chip LEDs 21 are fitted to form one coupled terminal portion 31E, and the coupled terminal portion 31E is soldered and connected to one common pad 33 which is disposed at a position of the substrate portion 20 at which the common pad 33 overlaps the coupled terminal portion 31E.

Accordingly, the number of pads necessary for mounting two chip LEDs 21 adjacent to each other is able to be reduced by one from four in the case of FIG. 7 to three in the case of FIG. 8. Accordingly, the distance (pitch) between the adjacent chip LEDs 21 is able to be further reduced from P1 illustrated in FIG. 7 to P2 illustrated in FIG. 8.

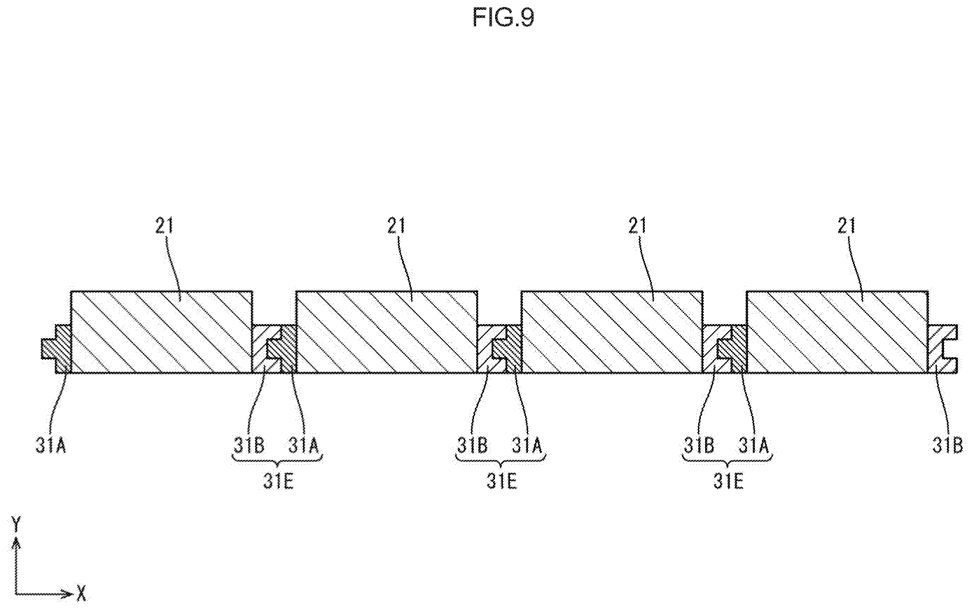

Further, as illustrated in FIG. 5, each of the chip LEDs 21 according to the present embodiment includes the first terminal portion 31A at one end portion in the row direction and the second terminal portion 31B at the other end portion in the row direction. This makes it possible to couple the chip LEDs 21 in a row via coupled terminal portions 31E as illustrated in FIG. 9.

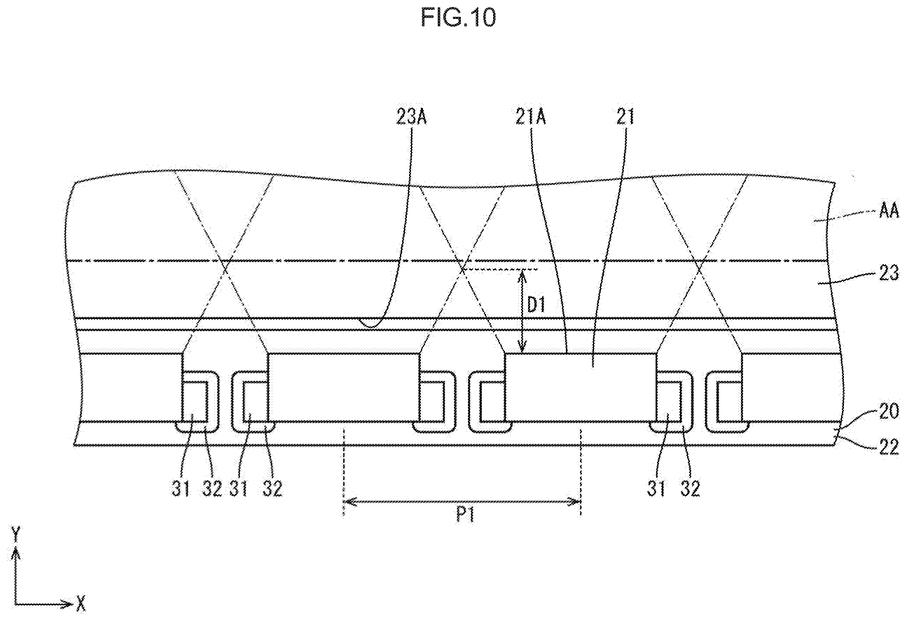

Further, as illustrated in FIG. 3, by connecting the coupled terminal portion 31E to the common pad 33, it is possible to omit one pad in each space between the chip LEDs 21, thus making it possible to reduce the distances between adjacent chip LEDs 21 by an amount corresponding to one pad. As a result, although the chip LEDs 21 are mounted at the pitch P1 in the related art as illustrated in FIG. 10, according to the present embodiment, it is possible to mount the chip LEDs 21 at the narrower pitch P2.

As described above, the LED substrate 22 according to the present embodiment includes the substrate portion 20, the chip LEDs 21 that are mounted on the substrate portion 20 in a row, the first terminal portion 31A that is included in any of the chip LEDs 21, the second terminal portion 31B that is included in a chip LED 21 of the chip LEDs 21, which is adjacent to the chip LED 21 including the first terminal portion 31A, and that is fitted to the first terminal portion 31A to thereby be coupled to the first terminal portion 31A, and the common pad 33 that is disposed at a position at which the common pad 33 overlaps the first terminal portion 31A and the second terminal portion 31B which fit each other on the substrate portion 20 and that is connected to the first terminal portion 31A and the second terminal portion 31B which fit each other.

Accordingly, the first terminal portion 31A included in one chip LED 21 and the second terminal portion 31B included in the other chip LED 21 adjacent to the one chip LED 21 are fitted and the two terminal portions 31A and 31B are coupled, and the two chip LEDs 21 are also coupled accordingly. Subsequently, relative displacement is regulated between the adjacent chip LEDs 21. Accordingly, occurrence of positional deviation of the adjacent chip LEDs 21 is suppressed on the substrate portion 20. If positional deviation occurs, directions of the chip LEDs 21 are not stably maintained, and a direction of light (optical axis) to be emitted varies regarding each of the chip LEDs 21, resulting in a deterioration in the uniformity of light emitted from the whole LED substrate 22. However, such malfunctioning is able to be prevented in the present embodiment.

Further, relative displacement of the coupled first terminal portion 31A and second terminal portion 31B is regulated, and the first terminal portion 31A and the second terminal portion 31B form one coupled terminal portion 31E that is coupled and are able to be collectively connected to one common pad 33 that is disposed at a position at which the common pad 33 overlaps the coupled terminal portion 31E on the substrate portion 20. As illustrated in FIG. 7, in the related art, when two chip LEDs 21 are mounted on the substrate portion 20, the pads 32 are provided so that each of the pads 32 corresponds to one terminal portion 31 on a one-to-one basis. This is because, when one pad 32 corresponds to one terminal portion 31, at a time of a reflow process, occurrence of positional deviation of the chip LEDs 21 is suppressed by a self-alignment effect.

However, when mounting the chip LEDs 21 at a narrower pitch is intended, it is not desirable to mount two terminal portions 31 on one pad 32 as they are. This is because, at the time of a reflow process, the two terminal portions 31 move around without restriction on molten solder on the one pad 32 and may interfere with each other, and it is therefore anticipated that positional deviation may occur between the adjacent chip LEDs 21. Thus, as illustrated in FIG. 7, the number of pads 32 necessary for mounting two chip LEDs 21 on the substrate portion 20 is four in the related art, which is the same as the total number of the terminal portions 31.

On the other hand, with the configuration according to the present embodiment, as illustrated in FIG. 8, the first terminal portion 31A and the second terminal portion 31B that are included in two adjacent chip LEDs 21 fit each other and form the coupled terminal portion 31E. As a result, the coupled terminal portion 31E acts as a single terminal and is therefore able to be soldered and connected to a single common pad 33 that is disposed at a position at which the common pad 33 overlaps the coupled terminal portion 31E on the substrate portion 20. That is, with the configuration according to the present embodiment, the total number of pads necessary for mounting two chip LEDs 21 on the substrate portion 20 is three (two pads 32 and one common pad 33).

Accordingly, it is possible to reduce the number of pads necessary for mounting two chip LEDs 21 adjacent to each other by one from four in the case of FIG. 7 to three in the case of FIG. 8. Accordingly, the distance (pitch) between the adjacent chip LEDs 21 is able to be further reduced from P1 illustrated in FIG. 7 to P2 illustrated in FIG. 8, and thus mounting at a narrow pitch is enabled.

When the distance between the chip LEDs 21 is able to be reduced, it is possible to reduce the size of an area in the vicinity of the LED substrate 22 not reached by the light from the chip LED 21, thus making it possible to make light emitted from the whole LED substrate 22 more uniform. As above, according to the present embodiment, it is possible to realize the LED substrate 22 in which the chip LEDs 21 are mounted at a narrow pitch and which is capable of more uniform light emission.

Further, the LED substrate 22 according to the present embodiment is provided with the first terminal portion 31A including the protrusion 31C that protrudes in the row direction of the chip LEDs 21 and the second terminal portion 31B including the recess 31D that accepts the protrusion 31C.

Accordingly, in a case where the chip LED 21 including the first terminal portion 31A and the chip LED 21 including the second terminal portion 31B are coupled, when at least one of the two chip LEDs 21 on the substrate portion 20 is displaced in a direction of mutual approach in the row direction and the protrusion 31C of the first terminal portion 31A is fitted into the recess 31D of the second terminal portion 31B, the first terminal portion 31A and the second terminal portion 31B fit each other and the two terminal portions 31A and 31B and the two chip LEDs 21 are coupled. Accordingly, relative displacement of the adjacent chip LEDs 21 is regulated, and occurrence of positional deviation particularly in a direction perpendicular to the row direction on the substrate portion 20 is able to be suppressed, such that a positional relationship between the respective chip LEDs 21 is able to be stably maintained. As above, it is possible to realize the LED substrate 22 that is capable of more uniform light emission.

Further, in the LED substrate 22 according to the present embodiment, each of the chip LEDs 21 includes the first terminal portion 31A at one end portion in the row direction and the second terminal portion 31B at the other end portion.

Accordingly, as illustrated in FIGS. 3 and 9, when the chip LEDs 21 are mounted on the substrate portion 20 in a row, the terminal portion 31A included in one chip LED 21 is fitted and coupled to the second terminal portion 31B included in an adjacent chip LED 21. Further, the first terminal portion 31A included in the adjacent chip LED 21 on a side opposite to the second terminal portion 31B is further fitted and coupled to the second terminal portion 31B included in an adjacent chip LED 21. By repeating this, it is possible to couple the chip LEDs 21 in a row via coupled terminals (coupled terminal portions 31E). Accordingly, relative displacement of each of the chip LEDs 21 with respect to the chip LED 21 adjacent thereto is regulated by the coupled terminal portion 31E, and occurrence of positional deviation on the substrate portion 20 is suppressed, such that it is possible to stably maintain the positional relationship between the respective chip LEDs 21.

Further, as illustrated in FIG. 3, when the coupled terminal portion 31E is connected to the common pad 33, it is possible to omit one pad in each space between the chip LEDs 21, such that each distance between adjacent chip LEDs 21 is able to be reduced by an amount corresponding to one pad and P2 is the resultant pitch. Although the chip LEDs 21 are mounted at the pitch P1 in the related art as illustrated in FIG. 10, with the configuration according to the present embodiment, it is possible to mount the chip LEDs 21, which are to be mounted in a row, at the pitch P2 which is narrower, while stably maintaining the positional relationship. Therefore, it is possible to realize the LED substrate 22 that emits more uniform light.

Further, the backlight device 12 according to the present embodiment includes the LED substrate 22 and the light guide plate 23 that includes the light entering end surface 23A on which light emitted from the chip LEDs 21 is incident and the light emitting plate surface 23B from which the incident light is emitted.

Accordingly, the light emitted by the light emitting surfaces 21A of the chip LEDs 21 is incident on the light entering end surface 23A of the light guide plate 23, repeatedly reflected within the light guide plate 23, and then emitted from the light emitting plate surface 23B. In FIGS. 3 and 10, each area which is demarcated by the light emitting surface 21A of the chip LED 21 and the two one-dot chain lines extending obliquely from two ends of the light emitting surface 21A is an area to which emitted light reaches directly, and the other areas are areas to which no emitted light reaches directly. That is, in FIG. 10 illustrating an embodiment according to the related art, when D1 is a distance from the light emitting surface 21A to a point at which the one-dot chain lines intersect in a normal direction, an area to which light from the light emitting surface 21A does not reach at all corresponds to a position which is not apart from the light emitting surface 21A by D1 or more. When the size of areas of the light guide plate 23 to which no emitted light directly reaches increases, luminance unevenness of the light emitting plate surface 23B is generated in the vicinity of the light emitting surfaces 21A, such that it is necessary to move the AA from the light emitting surfaces 21A to a position at which luminance unevenness is not generated. In this case, a picture-frame portion of the backlight device 12 is not able to be narrowed.

With the configuration according to the present embodiment, as illustrated in FIG. 3, the chip LEDs 21 are mounted on the LED substrate 22 at the pitch P2 which is narrower than the pitch P1 illustrated in FIG. 10, such that a distance D2 at which the one-dot chain lines intersect is narrower than D1 illustrated in FIG. 10. Accordingly, even in the vicinity of the light emitting surfaces 21A, it is possible to reduce an area to which no emitted light reaches directly, such that occurrence of luminance unevenness of the light emitting plate surface 23B in the vicinity of the light emitting surfaces 21A is able to be suitably suppressed. As a result, even when the AA is close to the vicinity of the light emitting surfaces 21A, luminance unevenness is less likely to be generated in the AA, and the picture-frame portion of the backlight device 12 is able to be further narrowed.

Accordingly, with such a configuration, even when a distance between the light emitting surfaces 21A of the chip LEDs 21 and the AA in plan view is reduced, occurrence of luminance unevenness on the light emitting plate surface 23B is suitably suppressed. It is thereby possible to narrow the picture-frame portion of the backlight device 12 while suppressing occurrence of luminance unevenness.

Further, the liquid crystal display device 10 according to the present embodiment includes the backlight device 12 and the liquid crystal panel (display panel) 11 that displays an image by utilizing light emitted from the backlight device 12.

Accordingly, light emitted from the light emitting plate surface 23B of the backlight device 12 illuminates a rear surface of the liquid crystal panel 11, and the liquid crystal panel 11 is able to display an image in the display area AA in a visually recognizable state by utilizing the light. Here, since occurrence of luminance unevenness on the light emitting plate surface 23B is suitably suppressed in the backlight device 12, the backlight device 12 emits uniform light to the rear surface of the liquid crystal panel 11, and the liquid crystal panel 11 is thereby able to display a high-quality image on the front surface thereof. In addition, since the picture-frame portion of the backlight device 12 is narrowed, it is also possible to achieve picture-frame narrowing of the liquid crystal display device 10 including the backlight device 12.

### Embodiment 2

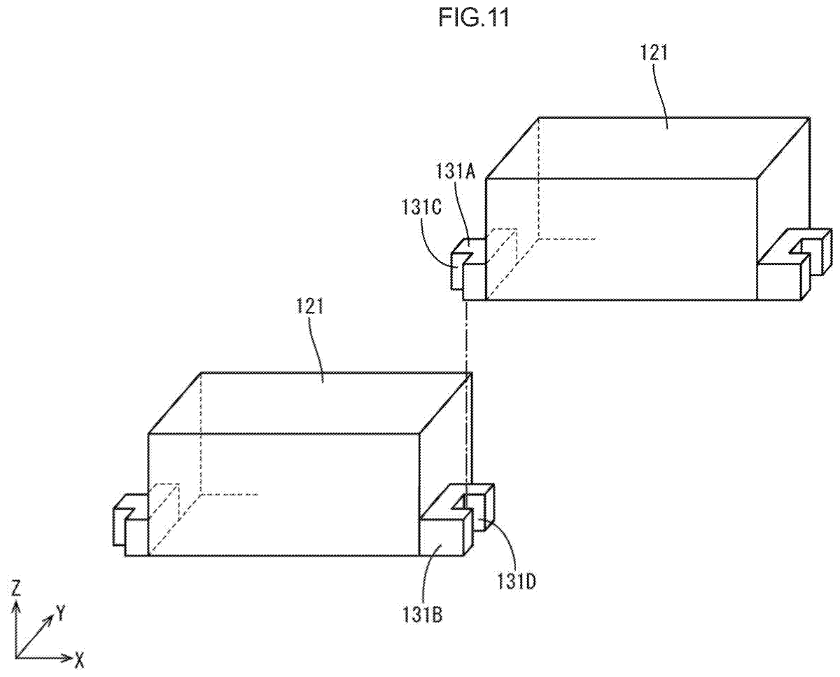

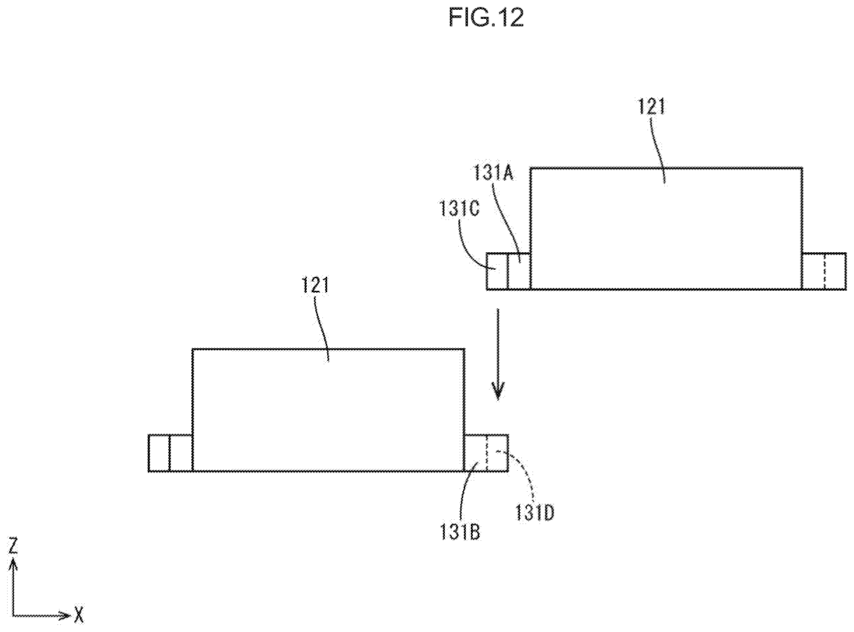

Embodiment 2 of the invention will be described with reference to FIGS. 11 and 12. The present embodiment is an embodiment having a configuration which is different from that of Embodiment 1 in shapes of a first terminal portion 131A and a second terminal portion 131B. Specifically, a protrusion 131C included in the first terminal portion 131A has a shape that protrudes in a row direction of chip LEDs 121 in plan view, and a recess 131D included in the second terminal portion 131B has a recessed shape that accepts the protrusion 131C in plan view. Note that, an element that has a configuration similar to that of Embodiment 1 described above will be given the same reference sign, and redundant description of a structure, an action, and an effect thereof will be omitted.

As illustrated in FIG. 12, one chip LED 121 that includes the first terminal portion 131A and a different chip LED 121 that is adjacent thereto and includes the second terminal portion 131B are able to be coupled when the different chip LED 121 is brought close to the one chip LED 121 so that the first terminal portion 131A of the one chip LED 121 and the second terminal portion 131B of the different chip LED 121 overlap.

In the present embodiment, as in a case of Embodiment 1, by displacing the two adjacent chip LEDs 121 in the row direction so as to come close to each other, it is possible to fit the two terminal portions 131A and 131B to each other, and, in addition, also when the two terminal portions 131A and 131B included in the two chip LEDs 121 are brought close so as to overlap, it is possible to fit the two terminal portions 131A and 131B to each other, such that it is possible to select a fitting method as appropriate in response to a situation at a time of mounting. Generally, when an electronic component is mounted on a surface of a substrate by using a chip mounter, the electronic component is brought close to a pad on the substrate in a direction perpendicular to the surface of the substrate and is mounted on the substrate in many cases. Thus, the present embodiment is advantageous particularly in such a case. Further, relative displacement of the adjacent chip LEDs 121, in particular, occurrence of positional deviation in a direction perpendicular to the row direction is suppressed on the substrate portion 20.

### Embodiment 3

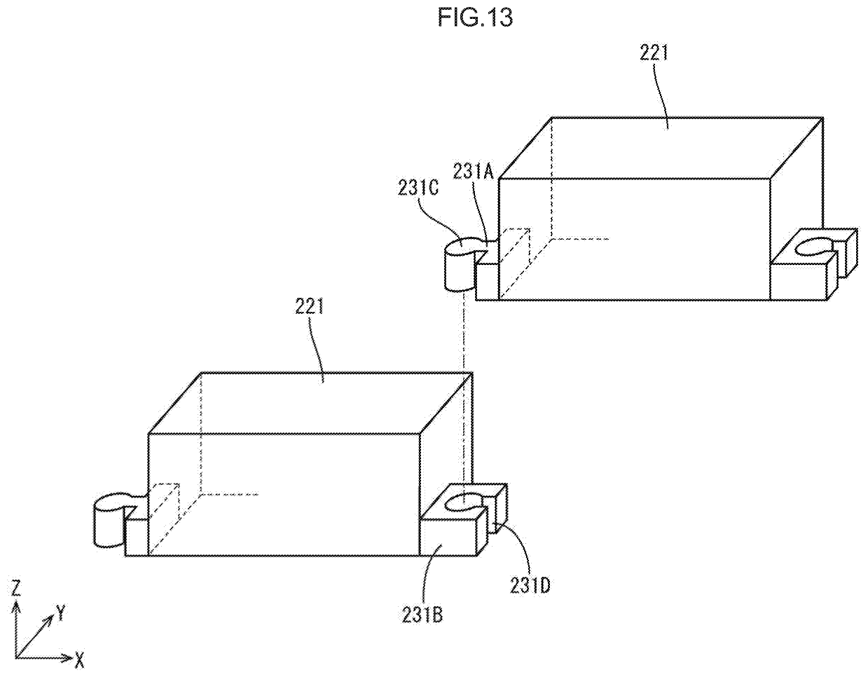

Embodiment 3 of the invention will be described with reference to FIGS. 13 to 15. The present embodiment is an embodiment having a configuration which is different from that of Embodiment 1 in a shape of each of a first terminal portion 231A and a second terminal portion 231B. Specifically, as illustrated in FIG. 13, a protrusion 231C included in the first terminal portion 231A has a shape that includes a portion a width of which is wider at a location further from the a chip LED 221 than at a location closer to the chip LED 221 in plan view.

Further, a recess 231D included in the second terminal portion 231B has a recessed shape that accepts the protrusion 231C in plan view. Specifically, the recess 231D of the second terminal portion 231B includes two protruding portions, which extend in a row direction, at two ends in a width direction of the recess 231D in plan view, and forms the recessed shape as a whole. An area between the two protruding portions of the recess 231D has a portion a width of which is narrower at a location further from the chip LED 221 than at a location closer to the chip LED 221. Note that, an element that includes a configuration similar to that of Embodiment 1 described above will be given the same reference sign, and redundant description of a structure, an action, and an effect thereof will be omitted.

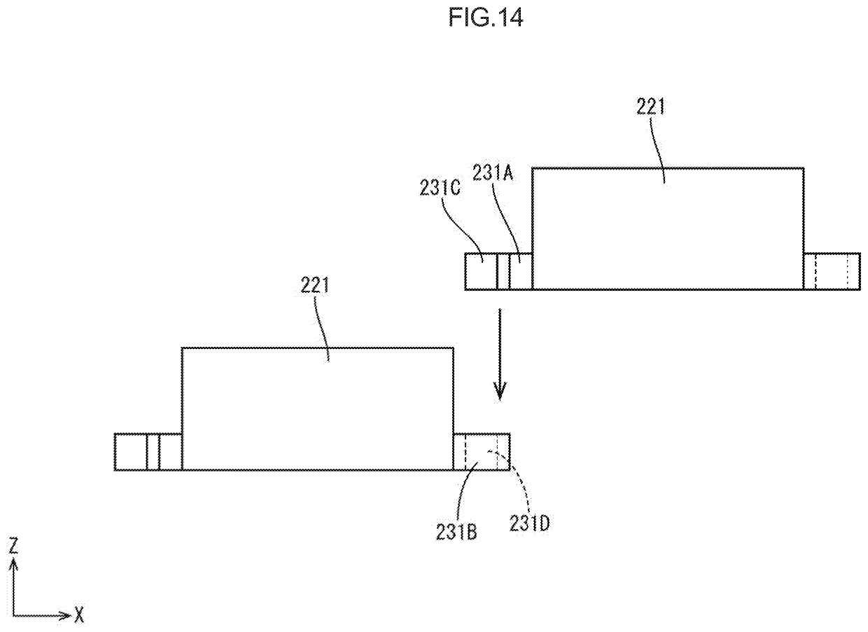

As illustrated in FIG. 14, one chip LED 221 that includes the first terminal portion 231A and a different chip LED 221 that is adjacent thereto and includes the second terminal portion 231B are able to be coupled when the different chip LED 221 is brought close to the one chip LED 221 so that the first terminal portion 231A of the one chip LED 221 and the second terminal portion 231B of the different chip LED 221 overlap.

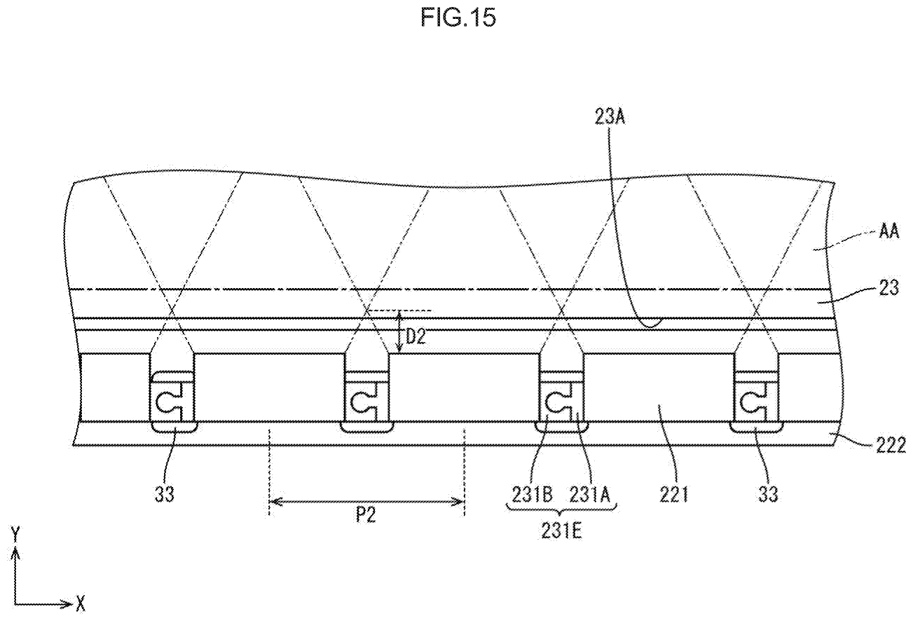

In this case, the protrusion 231C according to the present embodiment has the portion the width of which is wider at a location further from the chip LED 221 than at a location closer to the chip LED 221. Accordingly, when the first terminal portion 231A and the second terminal portion 231B fit each other, relative displacement in a direction perpendicular to the row direction on the substrate portion 20 is regulated, and, in addition, relative displacement in a direction parallel to the row direction, in particular, in a direction in which the two adjacent chip LEDs 221 move away from each other is regulated. Accordingly, in addition to the direction perpendicular to the row direction on the substrate portion 20, occurrence of positional deviation in the direction parallel to the row direction is also able to be suppressed, such that it is possible to realize an LED substrate 222 that is capable of more uniform light emission (FIG. 15).

### Embodiment 4

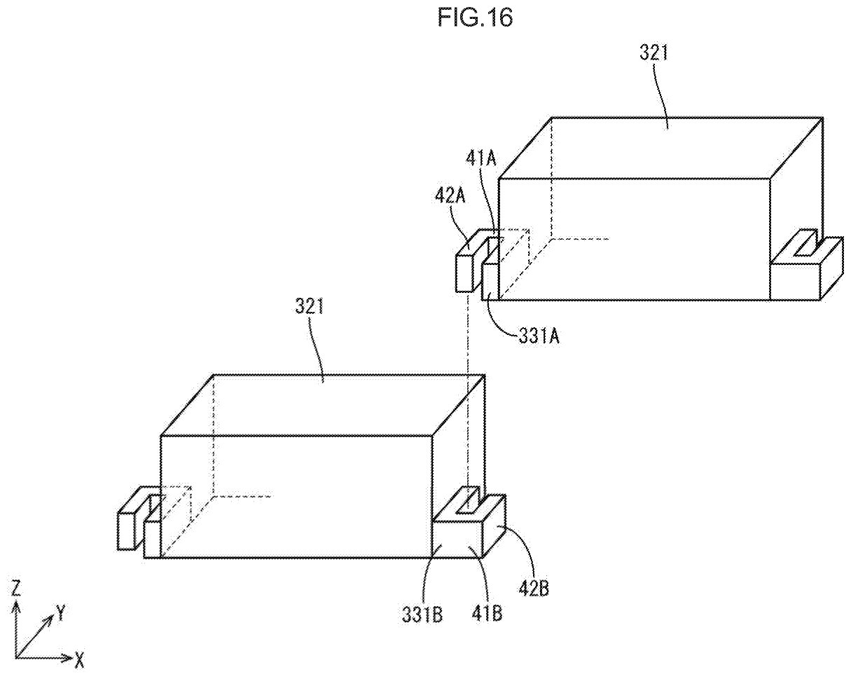

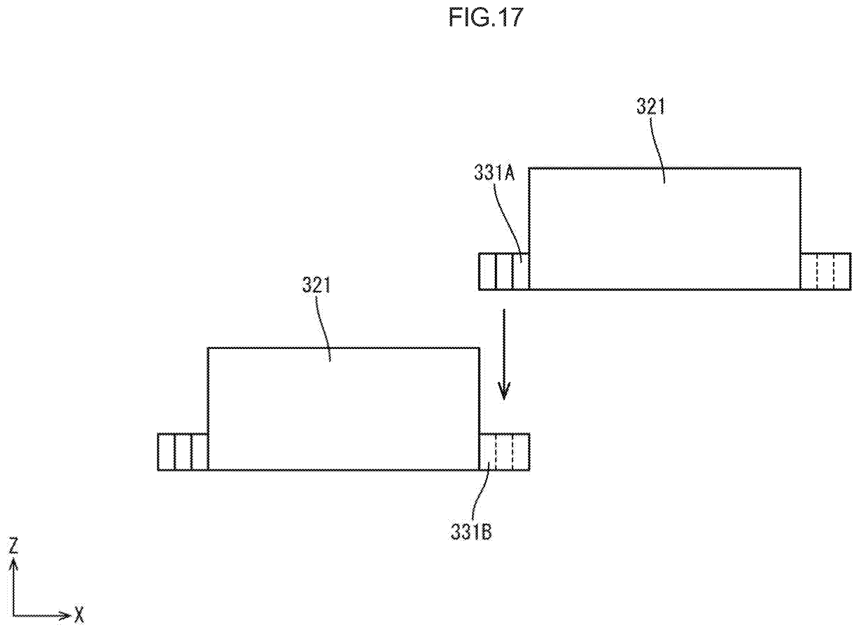

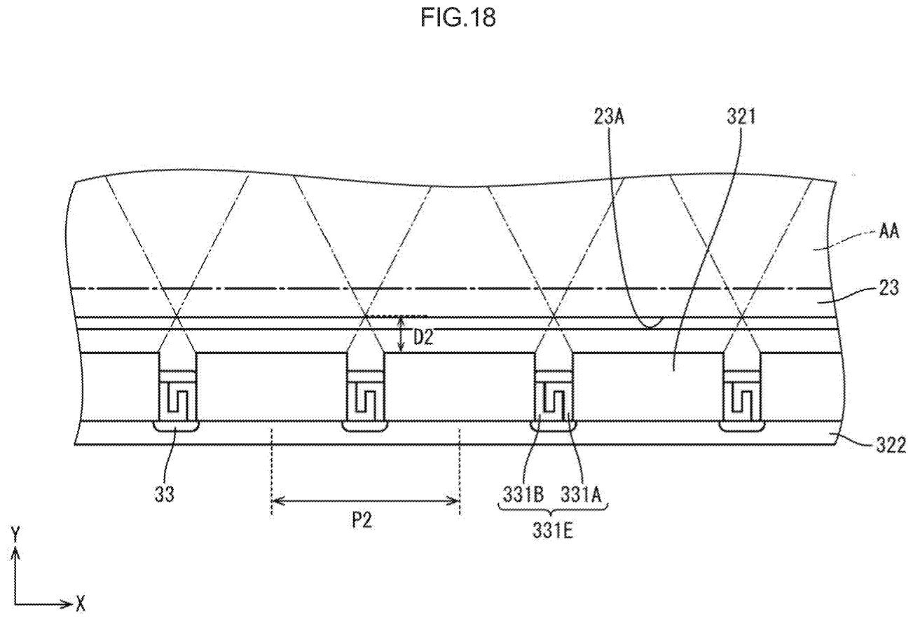

Embodiment 4 of the invention will be described with reference to FIGS. 16 to 18. The present embodiment is an embodiment having a configuration which is different from that of Embodiment 1 in shapes of a first terminal portion 331A and a second terminal portion 331B. Specifically, as illustrated in FIG. 16, the first terminal portion 331A included in one chip LED 321 of two adjacent chip LEDs 321 includes a first protruding portion 41A that projects to a side of the second terminal portion 331B and a first angled portion 42A that is bent from a tip end of the projection of the first protruding portion 41A. Further, the second terminal portion 331B included in the other chip LED 321 includes a second protruding portion 41B that projects to a side of the first terminal portion 331A and a second angled portion 42B that is bent from a tip end of the projection of the second protruding portion 41B. Note that, an element that includes a configuration similar to that of Embodiment 1 described above will be given the same reference sign, and redundant description of a structure, an action, and an effect thereof will be omitted.

As illustrated in FIG. 17, in one chip LED 321 that includes the first terminal portion 331A and a different chip LED 321 that is adjacent thereto and includes the second terminal portion 331B, the two terminal portions 331A and 331B are coupled when the different chip LED 321 is brought close to the one chip LED 321 so that the first terminal portion 331A of the one chip LED 321 and the second terminal portion 331B of the different chip LED 321 overlap, and the adjacent two chip LEDs 321 are also coupled.

Accordingly, relative displacement of the adjacent chip LEDs 321 on the substrate portion 20, in particular, occurrence of positional deviation in a direction in which the chip LEDs 321 come close to each other and in a direction in which the chip LEDs 321 move away from each other is able to be suppressed, such that a positional relationship of the respective chip LEDs 321 is able to be stably maintained, thus making it possible to realize an LED substrate 322 that is capable of more uniform light emission.

### OTHER EMBODIMENTS

The invention is not limited to the embodiments described based on the description above and the drawings, and, for example, the following embodiments are also included in the technical scope of the invention.

(1) Although a case where the liquid crystal panel having the quadrangular shape is used as the display device has been described in each of the above-described embodiments, a shape of the liquid crystal panel according to the invention is not limited to the quadrangular shape, and may be a circular shape, an elliptical shape, a polygonal shape, or other shapes. In any case, an LED substrate is disposed along part of an outer periphery of the liquid crystal panel.

(2) Although a case where the backlight of the edge light type is used as the backlight device has been described in each of the above-described embodiments, the invention may also be applied to a case where chip LEDs are mounted on a rear side of a liquid crystal panel at a narrow pitch in a direct backlight.

(3) Although a case where the chip LEDs of the side light emitting type are used has been exemplified in each of the above-described embodiments, the invention may also be applied to chip LEDs of a top light emitting type. In this case, a substrate portion on which the chip LEDs are mounted is disposed so as to be parallel to an XZ plane.

(4) Although a case where the flexible printed circuit board (FPC) is used as the substrate portion on which the chip LEDs are mounted has been exemplified in each of the above-described embodiments, the invention may also be applied to a case where a rigid printed circuit board is used as a substrate portion.

(5) Although a case where the LED substrate is disposed along the long side of the liquid crystal panel has been exemplified in each of the above-described embodiments, a configuration in which an LED substrate is disposed along a short side may be provided.

What is claimed is:

1. A light source substrate comprising:
a substrate portion;
a plurality of light sources mounted on the substrate portion in a row;
a first terminal portion that is included in any of the plurality of light sources;
a second terminal portion that is included in a light source, which is adjacent to the light source including the first terminal portion, of the plurality of light sources and that is fitted to the first terminal portion to be coupled to the first terminal portion; and
a common pad that is disposed at a position at which the common pad overlaps the first terminal portion and the second terminal portion which fit each other on the substrate portion and that is connected to the first terminal portion and the second terminal portion which fit each other.

2. The light source substrate according to claim 1, wherein
the first terminal portion includes a protrusion that protrudes in a row direction of the light sources, and
the second terminal portion includes a recess that accepts the protrusion.

3. The light source substrate according to claim 2, wherein
the protrusion has a shape that protrudes in the row direction of the light sources in plan view, and
the recess has a recessed shape that accepts the protrusion in plan view.

4. The light source substrate according to claim 2, wherein
the protrusion has a shape including a portion a width of which is wider at a location further from the light source than at a location closer to the light source in plan view, and
the recess has a recessed shape that accepts the protrusion in plan view.

5. The light source substrate according to claim 1, wherein
the first terminal portion includes a first protruding portion that projects to a side of the second terminal portion and a first angled portion that is bent from a tip end of a projection of the first protruding portion, and
the second terminal portion includes a second protruding portion that projects to a side of the first terminal portion and a second angled portion that is bent from a tip end of a projection of the second protruding portion.

6. The light source substrate according to claim 1, wherein each of the plurality of light sources includes the first terminal portion at one end portion in a row direction and includes the second terminal portion at the other end portion.

7. A backlight device comprising:
the light source substrate according to claim 1; and
a light guide plate that includes a light entering end surface on which light emitted from the light sources is incident and a light emitting plate surface from which the light is emitted.

8. A display device comprising:
the backlight device according to claim 7; and
a display panel that displays an image by utilizing light emitted from the backlight device.
